(19) United States
(12) Patent Application Publication
(10) Pub. No.: US 2023/0163065 A1
(43) Pub. Date: May 25, 2023

(54) STACK TYPE SEMICONDUCTOR DEVICE AND METHOD OF MANUFACTURING THE SAME

(71) Applicant: SK hynix Inc., Icheon-si Gyeonggi-do (KR)

(72) Inventor: Seong Hwi SONG, Icheon-si Gyeonggi-do (KR)

(73) Assignee: SK hynix Inc., Icheon-si Gyeonggi-do (KR)

(21) Appl. No.: 17/735,755

(22) Filed: May 3, 2022

(30) Foreign Application Priority Data
Nov. 25, 2021 (KR) 10-2021-0164534

(51) Int. Cl. H01L 23/522; H01L 23/00; H01L 23/48; H01L 21/66; H01L 21/78; H01L 21/56

(52) U.S. Cl. CPC H01L 23/5226; H01L 24/08; H01L 23/481; H01L 24/05; H01L 22/32; H01L 24/80; H01L 22/14; H01L 21/78; H01L 21/561; H01L 24/94; H01L 2224/08146; H01L 2224/05647; H01L 2224/80895; H01L 2224/80896

(57) ABSTRACT

A stack type semiconductor device includes a stack wafer structure and a conductive path. The stack wafer structure includes a plurality of wafers that are hybrid-bonded to each other. Each of the wafers includes one or more semiconductor chips. The conductive path includes a plurality of vertical connection structures and one or more horizontal connection structures. The vertical connection structure is formed through the stack wafer structure. The horizontal connection structure is configured to connect the vertical connection structures.

### CROSS-REFERENCES TO RELATED APPLICATION

The present application claims priority under 35 U.S.C. § 119(a) to Korean application number 10-2021-0164534, filed on Nov. 25, 2021, in the Korean Intellectual Property Office, which is incorporated herein by reference in its entirety.

### BACKGROUND

### 1. Technical Field

Various embodiments generally relate to a semiconductor integrated circuit technology, more particularly, to a stack type semiconductor device capable of testing a bonding error after a hybrid bonding process, and a method of manufacturing the stack type semiconductor device.

### 2. Related Art

As a high-integrated circuit device is continuously developed, a pitch size of the integrated circuit device may be decreased. Thus, a packaging technology of the high-integrated circuit device may also be developed. The packaging technology may include a ball grid array (BGA), a chip scale package (CSP), a wafer level package (WLP), a three-dimensional package, a system in package (SIP), etc.

Currently, a three-dimensional stack type package may be proposed. The three-dimensional stack type packages may be formed by bonding wafers to each other and then sawing the bonded wafers to form the packages. The packaging process may be performed at a wafer unit so that fabrication processes may be reduced and the packages may each have a small size.

### SUMMARY

In one embodiment, a stack type semiconductor device may include a stack wafer structure and a conductive path. The stack wafer structure may include a plurality of wafers that are hybrid-bonded to each other. Each of the wafers may include one or more semiconductor chips. The conductive path may include a plurality of vertical connection structures and one or more horizontal connection structures. The vertical connection structures may be formed through the stack wafer structure. The horizontal connection structures may be configured to connect the vertical connection structures.

In one embodiment, a stack type semiconductor device may include a first wafer, a second wafer, a conductive path, a transmitter, and a receiver. The first wafer and the second wafer may be bonded to each other via a plurality of bonding patterns, the plurality of bonding patterns including a plurality of layers. Each of the first and second wafers may include a one or more semiconductor chips. The conductive path may be configured to extend through the first and second wafers. The transmitter may be connected to a first end of the conductive path to receive a test voltage. The receiver may be connected to a second end of the conductive path to detect a current that is generated from the test voltage.

In one embodiment, according to a method of manufacturing a stack type semiconductor device, bonded wafers may be formed by hybrid-bonding a plurality of wafers. A test current may be provided to the bonded wafers by applying a test bias (voltage) to a conductive path through the bonded wafers, where an open circuit in the conductive path results in a test current of zero amperes. A bonding error of the bonded wafers may be determined by measuring the test current. The bonded wafers may be sawed into a plurality of semiconductor chips. Each of the semiconductor chips may then be packaged.

In one embodiment, a stack type semiconductor device may include a stack wafer structure including a plurality of connection structures. The plurality of wafers may be hybrid-bonded to each other. A plurality of connection structures may be in each of the plurality of wafers. The plurality of connection structures may form a conductive path for a test current, the conductive path interconnecting the plurality of wafers.

### BRIEF DESCRIPTION OF THE DRAWINGS

The above and other aspects, features, and advantages of the subject matter of the present disclosure will be more clearly understood from the following detailed description taken in conjunction with the accompanying drawings, in which:

FIG. 1 is a perspective view illustrating a stack type semiconductor device in accordance with example embodiments;

FIGS. 2A and 2B are plan views illustrating an upper surface and a bottom surface of a wafer in a stack type semiconductor device in accordance with example embodiments;

FIG. 3 is a perspective view illustrating a plurality of bonded semiconductor chips in accordance with example embodiments;

FIG. 4A is a perspective view illustrating a stack type semiconductor device to which a face-to-face bonding process is applied in accordance with example embodiments;

FIG. 4B is a perspective view illustrating a stack type semiconductor device to which a back-to-back bonding process is applied in accordance with example embodiments;

FIG. 5A is a plan view illustrating a semiconductor chip of a first wafer in a stack type semiconductor device in accordance with example embodiments;

FIG. 5B is a plan view illustrating a semiconductor chip of a second wafer bonded to the semiconductor chip in FIG. 5A by a face-to-face bonding process in accordance with example embodiments;

FIGS. 6A and 6B are cross-sectional views illustrating a stack type semiconductor device in accordance with example embodiments;

FIG. 7 is a cross-sectional view illustrating a conductive path in a stack type semiconductor device in accordance with example embodiments;

FIGS. 8A and 8B are plan views illustrating a transmitter and a receiver in a stack type semiconductor device in accordance with example embodiments;

FIG. 9 is an enlarged cross-sectional view illustrating a stack type semiconductor device bonded by a face-to-face bonding process in accordance with example embodiments;

FIG. 10 is an enlarged cross-sectional view illustrating a hybrid bonding pattern of a stack type semiconductor device in accordance with example embodiments;

FIG. 11 is an enlarged cross-sectional view illustrating a stack type semiconductor device including stacked four wafers in accordance with example embodiments;

FIG. 12 is an enlarged cross-sectional view illustrating a stack type semiconductor device including two wafers bonded by a face-to-face bonding process in accordance with example embodiments;

FIG. 13 is an enlarged cross-sectional view illustrating a stack type semiconductor device including four wafers bonded by various techniques in accordance with example embodiments; and

FIG. 14 is a flow chart illustrating a method of manufacturing a stack type semiconductor device in accordance with example embodiments.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The present disclosure describes various embodiments with reference to the provided illustrations. However, the present disclosure should not be construed as being limited to the disclosed embodiments. Although a few embodiments of the present disclosure will be shown and described, it will be appreciated by those of ordinary skill in the art that changes may be made to provide other embodiments without departing from the principles and spirit of the present disclosure.

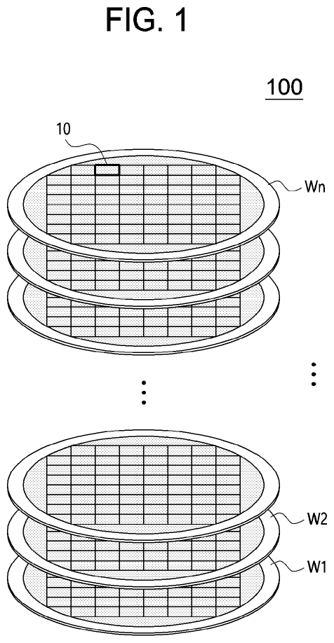

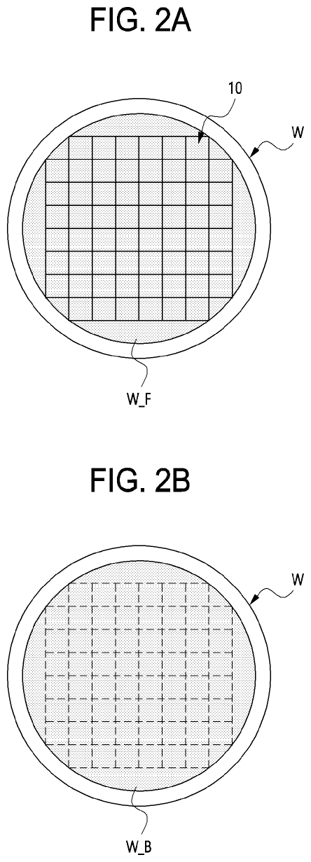

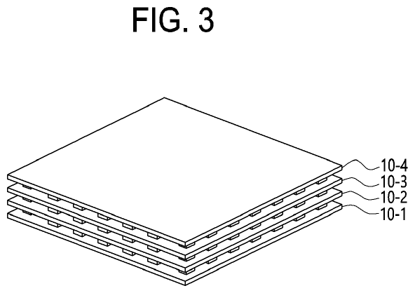

FIG. 1 is a perspective view illustrating a stack type semiconductor device in accordance with example embodiments, FIGS. 2A and 2B are plan views illustrating an upper surface and a bottom surface of a wafer in a stack type semiconductor device in accordance with example embodiments and FIG. 3 is a perspective view illustrating a plurality of bonded semiconductor chips in accordance with example embodiments.

Referring to FIG. 1, a stack type semiconductor device 100 may include a plurality of stacked wafers W1˜Wn. Each of the wafers W1˜Wn may include a plurality of semiconductor chips 10.

Referring to FIGS. 2A and 2B, the wafer W may include an upper surface W_F and a bottom surface W_B, the bottom surface W_B being on the opposite side of the upper surface W_F. For example, a device layer may be formed on the upper surface W_F of the wafer W. At least one bonding pattern may be formed on at least one of the upper surface W_F and the bottom surface W_B of the wafer W. The bonding pattern may be electrically connected to a through silicon via (TSV) that is formed through the wafer W.

As mentioned above, the TSV may be an electrode that is formed through the wafer W. The plurality of wafers W1˜Wn may be stacked through a hybrid bonding process. The hybrid bonding process may be a technique of attaching the bonding patterns of the wafers W1˜Wn. The bonding patterns may include a conductive material and an insulating material. The hybrid bonding process may be interpreted as a direct bonding interconnection process or a fusion boding process.

However, after wafers W1˜Wn are stacked through the hybrid bonding process, a bonding failure, such as a wafer crack, a misalignment between the bonding patterns, etc., might not be detected, because there is no test process between the hybrid bonding process stage and the packaging test stage. Thus, a packaging process may be performed after the wafers are divided into bonded chips 10-1˜10-4, as shown in FIG. 3, without said test process, resulting in the bonding failure remaining undiscovered. After the multi-chip package is completed through the packaging process, the packaging test may be performed on the multi-chip package. When an error is detected in the packaging test, it may be difficult to accurately determine which process resulted in the error.

According to example embodiments, the stack type semiconductor device 100 may provide a conductive path, extended by way of the bonded wafers, through which a test current may flow. Thus, the bonding failure may be monitored after the bonding process.

The bonded wafers or the bonded semiconductor chips may include a test pad region in which test pads may be arranged. The test pad region may include a conductive path configured to conduct a test current in vertical and horizontal directions. A test bias (voltage) may be applied to one end of the conductive path. The amount of the test current that flows through the conductive path may be detected at the other end of the conductive path to monitor problems, such as a bonding failure, a crack, etc.

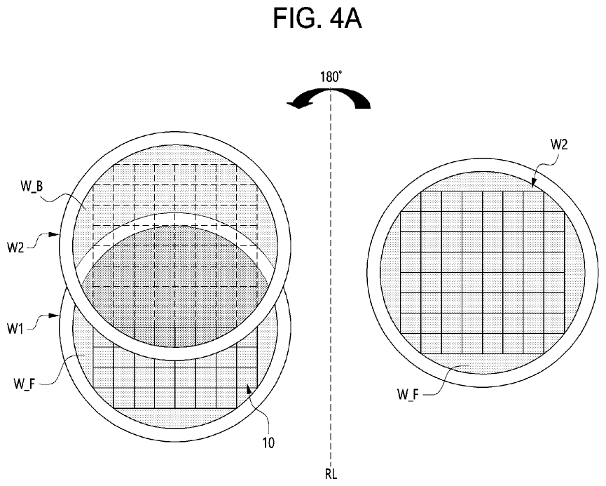

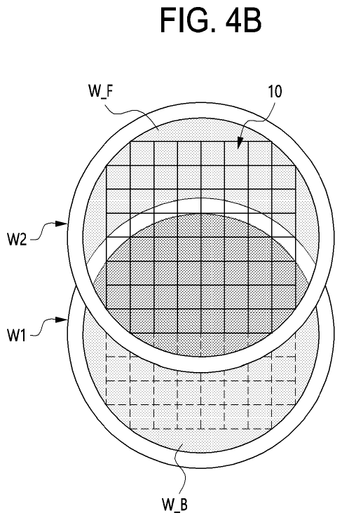

FIG. 4A is a perspective view illustrating a stack type semiconductor device to which a face-to-face bonding process is applied in accordance with example embodiments, and FIG. 4B is a perspective view illustrating a stack type semiconductor device to which a back-to-back bonding process is applied in accordance with example embodiments. FIGS. 4A and 4B may show only two wafers for conveniences of explanations.

Referring to FIG. 4A, an upper surface W_F of a first wafer W1 may face an upper surface W_F of the second wafer W2. The first wafer W1 may then be bonded to the second wafer W2. That is, the second wafer W2, which is flipped at an angle of about 180° based on a virtual reference line RL, may be bonded to the upper surface W_F of the first wafer W1. This bonding process in which the upper surfaces W_F of the first and second wafers W1 and W2 faces to each other may be referred to as a face-to-face bonding process.

Referring to FIG. 4B, a bottom surface W_B of the first wafer W1 may face a bottom surface W_B of the second wafer W2. The first wafer W1 may then be bonded to the second wafer W2. This bonding process in which the bottom surfaces W_B of the first and second wafers W1 and W2 face each other may be referred to as a back-to-back bonding process.

Alternatively, the upper surface W_F of the first wafer W1 may be bonded to the bottom surface W_B of the second wafer W2.

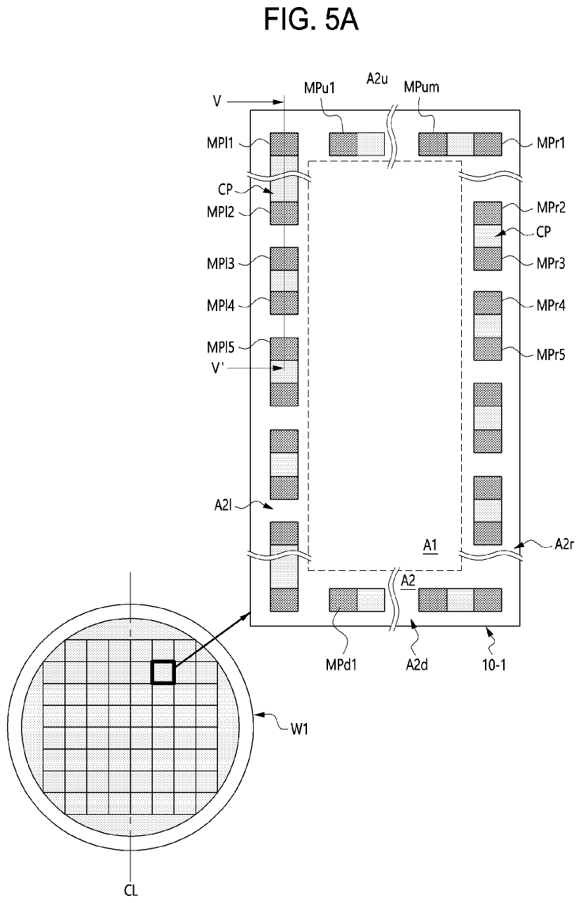

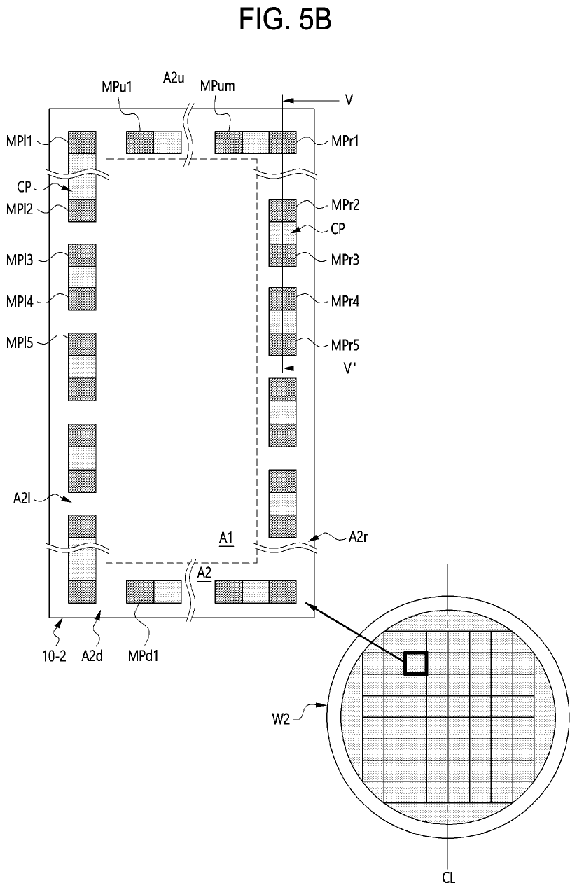

FIG. 5A is a plan view illustrating a semiconductor chip of a first wafer in a stack type semiconductor device in accordance with example embodiments, and FIG. 5B is a plan view illustrating a semiconductor chip of a second wafer bonded to the semiconductor chip in FIG. 5A by a face-to-face bonding process in accordance with example embodiments.

Referring to FIGS. 5A and 5B, the first wafer W1 and the second wafer W2 may be stacked with their upper surfaces facing each other. For example, a first semiconductor chip 10-1 of the first wafer W1 and a second semiconductor chip 10-2 of the second wafer W2 may face each other. When the first wafer W1 and the second wafer W2 have the same structure, the position of the first semiconductor chip 10-1 is different from that of the second semiconductor chip 10-2. For example, the first semiconductor chip 10-1 and the second semiconductor chip 10-2 may be symmetrically arranged with respect to a center line CL of the first or second wafers W1 or W2.

For example, the first and second semiconductor chips 10-1 and 10-2 may include a main region A1 and an edge region A2. Semiconductor integrated circuits may be arranged in the main region A1. The edge region A2 may be configured to surround the main region A1. At least one test pad may be arranged in the edge region A2.

In order to explain a connection between monitoring patterns in the face-to-face bonding process, the edge region A2 may be divided into a left edge region A2l, a right edge region A2r, an up edge region A2u, and a down edge region A2d.

The monitoring patterns MP may include left monitoring patterns MPl1˜MPln in the left edge region A2l, right monitoring patterns MPr1˜MPrn in the right edge region A2r, up monitoring patterns MPu1˜MPum in the up edge region A2u, and down monitoring patterns MPd1˜MPdm in the down edge region A2d.

Each of the monitoring patterns MP may be a part of a vertical connection structure that is formed through the semiconductor chips 10-1 and 10-2. For example, the monitoring pattern MP may be a bonding pattern or a pad electrode that is connected to the vertical connection structure in the edge region A2. Although not depicted in the drawings, a signal transmission pad may also be formed in the main region A1.

Further, the semiconductor chips 10-1 and 10-2 may include a connection pattern CP configured to connect the adjacent monitoring patterns MP with each other, thereby providing a horizontal conductive path. For example, the monitoring pattern MP may be connected to any one of the adjacent monitoring patterns through the connection pattern CP. In contrast, the monitoring pattern MP may be spaced apart from the remaining monitoring pattern.

For example, the second left monitoring pattern MPl2 of the first and second semiconductor chips 10-1 and 10-2 may be connected to the adjacent first left monitoring pattern MPl1 through the connection pattern CP. In contrast, the second left monitoring pattern MPl2 may be electrically isolated from the third left monitoring pattern MPl3. Further, the fourth left monitoring pattern MPl4 may be connected to the adjacent third left monitoring pattern MPl3 through the connection pattern CP. In contrast, the fourth left monitoring pattern MPl4 may be electrically isolated from the fifth left monitoring pattern MPl5.

The second right monitoring pattern MPr2, which may be eventually bonded to the second left monitoring pattern MPl2, may be electrically isolated from the adjacent first right monitoring pattern MPr1. In contrast, the second right monitoring pattern MPr2 may be electrically connected to the third right monitoring pattern MPr3 through the connection pattern CP. The fourth right monitoring pattern MPr4, which may be eventually bonded to the fourth left monitoring pattern MPl4, may be electrically isolated from the adjacent third right monitoring pattern MPr3. In contrast, the fourth right monitoring pattern MPr4 may be electrically connected to the fifth right monitoring pattern MPr5 through the connection pattern CP.

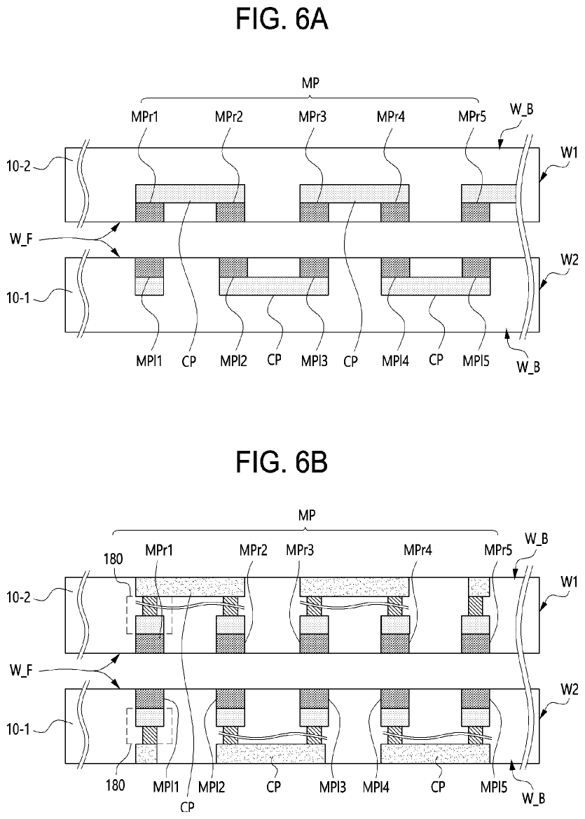

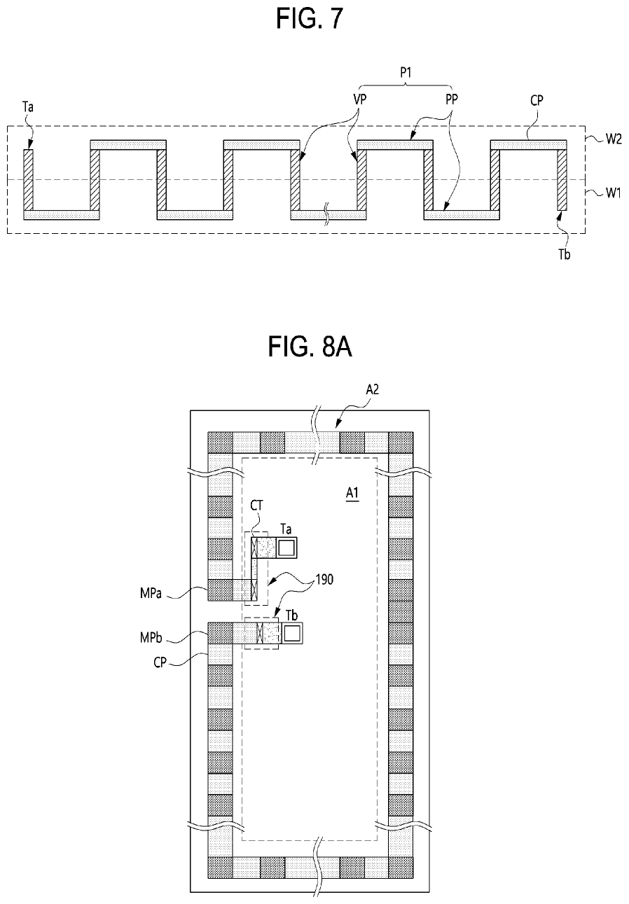

FIGS. 6A and 6B are cross-sectional views illustrating a stack type semiconductor device in accordance with example embodiments, and FIG. 7 is a cross-sectional view illustrating a conductive path in a stack type semiconductor device in accordance with example embodiments. FIGS. 6A and 6B are cross-sectional views taken along a line VI-VI′ in FIGS. 5A and 5B.

Referring to FIGS. 6A and 6B, the second wafer W2 may be positioned over the first wafer W1. The upper surface W_F of the first wafer W1 may face the upper surface W_F of the second wafer W2. Thus, the first to fifth right monitoring patterns MPr1˜MPr5 of the second semiconductor chip 10-2 may face the first to fifth left monitoring patterns MPl1˜MPl5 of the first semiconductor chip 10-1.

The connection pattern CP of the first semiconductor chip 10-1 may be connected between the second left monitoring pattern MPl2 and the third left monitoring pattern MPl3 and between the fourth left monitoring pattern MPl4 and the fifth left monitoring pattern MPl5. The connection pattern CP of the second semiconductor chip 10-2 may be connected between the first right monitoring pattern MPr1 and the second right monitoring pattern MPr2 and between the third right monitoring pattern MPr3 and the fourth right monitoring pattern MPr4.

In example embodiments, the connection pattern CP may include a metal wiring under the monitoring pattern CP.

For example, as shown in FIG. 6A, the connection pattern CP may be an uppermost metal interconnection layer under the monitoring pattern MP in the first or second wafer W1 or W2.

Alternatively, the connection pattern CP may include any one of a plurality of multi-interconnection layers. For example, a wiring structure 180 including at least one contact plug and at least one metal wiring may be interposed between the connection pattern CP and the monitoring pattern MP. The connection pattern CP may have various heights by inserting the wiring structure 180. As shown in FIG. 6B, the connection pattern CP may be exposed through the bottom surface W_B of the wafers W1, W2, or the semiconductor chips 10-1 and 10-2 by using the wiring structure 180.

Further, the connection pattern CP of the first wafer W1 and the connection pattern CP of the second wafer W2 may be alternately arranged so that the conductive path is not cut off.

Referring to FIG. 7, when the first wafer W1 and the second wafer W2 are bonded to each other, a vertical conductive path VP may be formed based on the vertical connection structure. Further, a horizontal conductive path PP may be formed based on the connection patterns CP that extend from both ends of the vertical conductive path VP in anti-parallel directions. The anti-parallel directions may be parallel directions having a phase difference of 180° or substantially 180°. Thus, an overlap portion might not exist between the connection pattern CP of the first wafer W1 and the connection pattern CP of the second wafer W2. As a result, a conductive path P1 including the vertical conductive path VP and the horizontal conductive path PP may be formed in the edge regions A2 of the first and second wafers W1 and W2.

In example embodiments, the monitoring pattern MP, corresponding to one end of the conductive path P1, may be set as a transmitter Ta. Another monitoring pattern MP that is electrically connected to the transmitter Ta, and may or may not be physically connected to the transmitter Ta, may be set as a receiver Tb. When a test bias (voltage) is applied to the transmitter Ta, a test current may flow through the conductive path P1 in vertical and horizontal directions of the first and second wafers W1 and W2. The receiver Tb may be electrically connected to a test current measurement member to measure the amount of the test current that is flowing in the conductive path P1 due to the test bias. A bonding error between the wafers W1 and W2 may be detected based on the amount of the test current that is detected by a test current measuring circuit (not shown).

For example, when a bonding error occurs between the first and second wafers W1 and W2, which are hybrid-bonded, the resistance of the conductive path P1 may be greatly increased due to the bonding error. Accordingly, a lower amount of test current may flow through the conductive path P1 than if there was no bonding error. Therefore, it may be seen that a bonding error between the bonded wafers may be readily detected by measuring the amount of the test current flowing through the conductive path P1. It may be noted that when the bonding error results in an open circuit in the conductive path P1, there is no current flowing in the conductive path P1.

In example embodiments, the transmitter Ta may be positioned at the second wafer W2, and the receiver Tb may be positioned at the first wafer W1. Alternatively, the transmitter Ta may be positioned at the first wafer W1, and the receiver Tb may be positioned at the second wafer W2. Further, both the transmitter Ta and the receiver Tb may be positioned at the first wafer W1 or the second wafer W2.

Further, the transmitter Ta and the receiver Tb may be positioned in the edge region A2. Alternatively, the transmitter Ta and the receiver Tb may be positioned in the main region A1. Still further, one of the transmitter Ta and the receiver Tb may be in the main region A1 and the other of the transmitter Ta and the receiver Tb may be in the edge region A2.

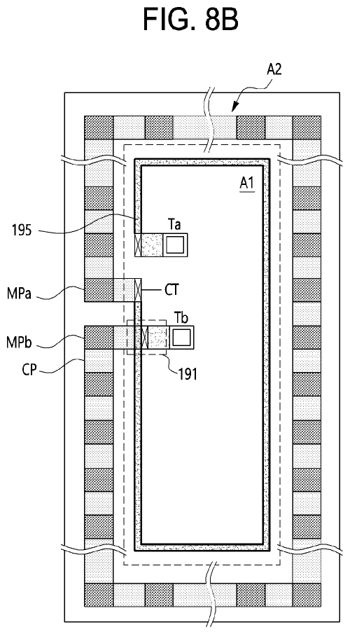

FIGS. 8A and 8B are plan views illustrating a transmitter and a receiver in a stack type semiconductor device in accordance with example embodiments.

Referring to FIG. 8A, the transmitter Ta may be arranged in the main region A1. The transmitter Ta may be electrically connected to a monitoring pattern MPa (hereinafter, transmission monitoring pattern) via a redistribution layer (RDL) 190.

A monitoring pattern MPb (hereinafter, reception monitoring pattern), which may be adjacent to the monitoring pattern MPa and physically spaced apart from the monitoring pattern MPa, may be electrically connected to the receiver Tb in the main region A1 via the RDL 190.

When the test bias (voltage) is applied to the transmitter Ta in the main region A1, the transmission monitoring pattern MPa may also have the test bias (voltage) via the RDL 190. A test current may result in the conductive path P1 due to the test bias, and the test current may be received by the receiver Tb, which may be electrically connected to the reception monitoring pattern MPb. The test current may then be measured by the test current measuring circuit (not shown). A bonding error of the wafers W1 and W2 may cause the resistance of the conductive path P1 to change, which may cause the test current to change as the test current is directly related to the resistance in the conductive path P1. Thus, the bonding error of the wafers W1 and W2, which are hybrid-bonded, may be detected (or monitored) based on the measured test current. Accordingly, the test bias (voltage) in the transmission monitoring pattern MPa may result in the test current to the reception monitoring pattern MPb through the conductive path P1 in the edge region A2. When the bonding error (or some other error such as a crack in the conductive path P1) results in an open circuit, the test current will be zero amperes.

Referring to FIG. 8B, a routing pattern 195 may be connected between the transmitter Ta and the transmission monitoring pattern MPa. The routing pattern 195 may be configured to surround the edge of the main region A1. The routing pattern 195 may include one end that is connected to the transmitter Ta and the other end that is connected to the transmission monitoring pattern MPa. The conductive path P1 in the edge region A2 may be connected between the transmission monitoring pattern MPa and the reception monitoring pattern MPb. The reception monitoring pattern MPb may be connected to the receiver Tb via an RDL 191. The routing pattern 195 may include a conductive layer on a level that is different from a level of the monitoring pattern MP and the connection pattern CP. A reference numeral CT may indicate a contact or a contact plug that is connected between metal wirings on different levels.

Thus, the bonded wafers or the bonded semiconductor chips may further include the routing pattern 195 that is on a different level than the vertical and horizontal conductive paths to monitor the crack and the bonding error at various positions of the bonded wafers.

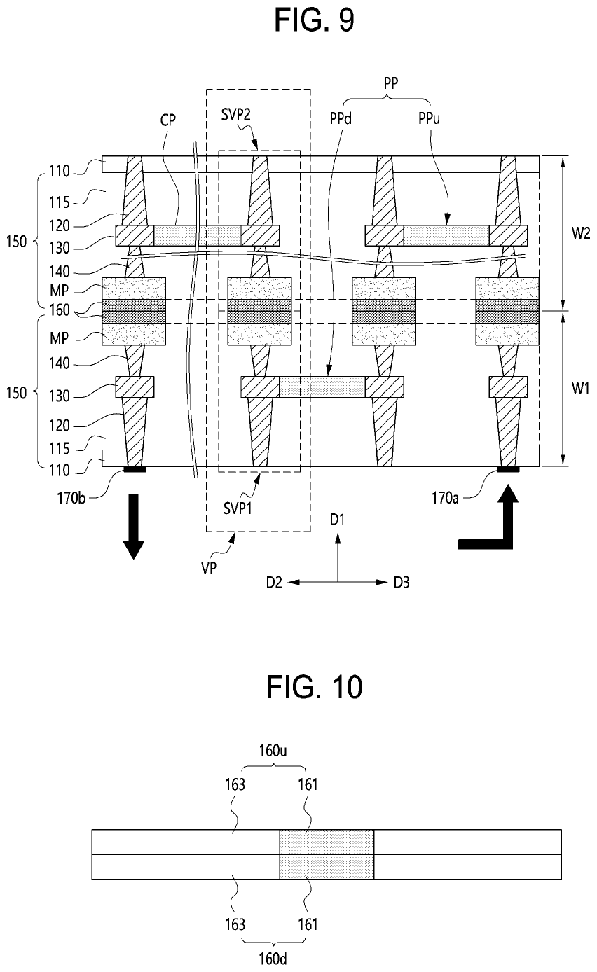

FIG. 9 is an enlarged cross-sectional view illustrating a stack type semiconductor device bonded by a face-to-face bonding process in accordance with example embodiments.

Referring to FIG. 9, the stack type semiconductor device may include the first and second wafers W1 and W2, which are hybrid-bonded. Each of the first and second wafers W1 and W2 may include a semiconductor substrate 110 and a device layer 150 that is integrated on the semiconductor substrate 110. Further, the first and second wafers W1 and W2 may be classified by a plurality of semiconductor chips. For reference, FIG. 9 shows portions of a semiconductor chip of the first wafer W1 and a semiconductor chip of the second wafer W2. As described above, each of the semiconductor chips may include the edge region A2 that surrounds the main region A1. In addition, the stack type semiconductor device may include the conductive path for detecting the bonding error. The conductive path may include a plurality of vertical connection structures VP and a plurality of horizontal connection structures PP. For example, the plurality of vertical connection structures VP and the plurality of horizontal connection structures PP may be arranged in the edge region A2 of each of the semiconductor chips of the wafers W1 and W2.

Each of the vertical connection structures VP may include a first sub-vertical connection structure SVP1 and a second sub-vertical connection structure SVP2. The first sub-vertical connection structure SVP1 may be positioned in the first wafer W1. The second sub-vertical connection structure SVP2 may be positioned in the second wafer W2. For example, the first and second sub-vertical connection structures SVP1 and SVP2 configured to receive a same signal may be bonded to each other to form the vertical connection structure VP.

The first sub-vertical connection structure SVP1 may include a TSV 120, a conductive pattern 130, a contact plug 140, a monitoring pattern MP, and a bonding pattern 160. The second sub-vertical connection structure SVP2 may include a bonding pattern 160, a contact plug 140, a conductive pattern 130, and a TSV 120. The vertical connection structure VP may extend in a first direction D1.

In example embodiments, the TSV 120 may be formed through the semiconductor substrate 110 of each of the wafers W1 and W2. The conductive pattern 130 and the contact plug 140 may be formed over the TSV 120 to be electrically coupled to the TSV 120. For example, the conductive pattern 130 may include at least one metal wiring pattern. The contact plug 140 may be formed between the metal wiring patterns. The conductive pattern 130 and the contact plug 140 may be positioned in the device layer 150. The monitoring pattern MP may be formed on the contact plug 140. In example embodiments, the contact plug 140 may include one conductive pattern that is formed between the conductive pattern 130 and the monitoring pattern MP. Alternatively, the contact plug 140 may include a multi-layered conductive pattern that is formed between the conductive pattern 130 and the monitoring pattern MP. For example, the monitoring pattern MP may include an uppermost metal layer of the multi-interconnection layers.

The bonding pattern 160 may include a copper layer having a high electrical conductivity and good electromigration.

The bonding pattern 160 of example embodiments may include a hybrid bonding pattern configured to stably bond the first and second wafers W1 and W2 to each other.

FIG. 10 is an enlarged cross-sectional view illustrating a hybrid bonding pattern of a stack type semiconductor device in accordance with example embodiments.

As shown in FIG. 10, a bonding pattern 160d of the first wafer W1 and a bonding pattern 160u of the second wafer W2 may include at least one metal pattern 161 and at least one insulation pattern 163, respectively. The metal pattern 161 and the insulation pattern 163 may be alternately arranged. For example, the metal pattern 161 may include a copper layer and the insulation pattern 163 may include a silicon oxide layer.

The bonding patterns 160d and 160u may be bonded through the hybrid bonding process with heat.

The vertical connection structure VP may provide a vertical conductive path configured to penetrate the stacked semiconductor chips or the stacked wafers.

The horizontal connection structure PP may be configured to electrically connect the adjacent vertical connection structures VP with each other. For example, the horizontal connection structure PP may include a connection pattern CP configured to connect conductive patterns or metal wirings in the vertical connection structures VP. As mentioned above, the connection pattern CP may be configured to connect the conductive patterns 130 of the adjacent vertical connection structures VP with each other. Alternatively, the connection pattern CP may be extended from the conductive pattern 130.

The horizontal connection structure PP may be connected to a lower end and an upper end of one vertical connection structure VP that are formed through the first and second semiconductor chips 10-1 and 10-2. A lower horizontal connection structure PPd, connected to the lower end of the vertical connection structure VP, may be positioned at the first semiconductor chip 10-1. The lower horizontal connection structure PPd may be extended in a second direction D2. The second direction D2 may be parallel to a surface of the semiconductor substrate 110. An upper horizontal connection structure PPu, connected to the upper end of the vertical connection structure VP, may be positioned at the second semiconductor chip 10-2. The upper horizontal connection structure PPu may be extended in a third direction D3. The third direction D3 may be slanted compared to the second direction D2 at an angle of about 180°. Thus, an overlap portion might not exist between the lower horizontal connection structure PPd and the upper horizontal connection structure PPu.

By continuously arranging the vertical connection structure VP and the horizontal connection structure PP in the edge region A2, the conductive path may be extended in the bonded wafers W1 and W2 along the vertical and horizontal directions.

A reference numeral 115 may indicate an insulation interlayer between the vertical connection structures VP. Reference numerals 170a and 170b may indicate test pads that are exposed through the bottom surface of the first wafer W1. For example, the test pad 170a may correspond to the transmitter Ta in FIGS. 8A and 8B. The test pad 170b may correspond to the receiver Tb in FIGS. 8A and 8B.

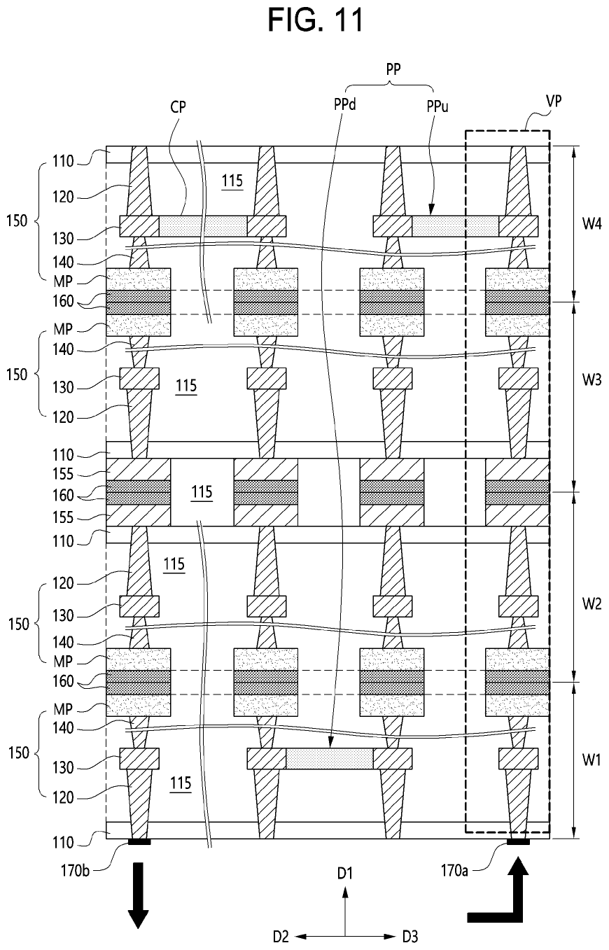

FIG. 11 is an enlarged cross-sectional view illustrating a stack type semiconductor device including stacked four wafers in accordance with example embodiments.

Referring to FIG. 11, first to fourth wafers W1˜W4 may be stacked. Each of the first to fourth wafers W1˜W4 may be divided into a plurality of semiconductor chips. The first to fourth wafers W1˜W4 may include corresponding pad structures.

For example, the first and second wafers W1 and W2 may be stacked in the face-to-face bonding process. The third and fourth wafers W3 and W4 may also be stacked in the face-to-face bonding process. The second and third wafers W2 and W3 may be stacked in the back-to-back bonding process.

In the back-to-back bonding process, the bottom surfaces of the wafers may face each other. For example, an external pad 155 may be arranged on the bottom surfaces of the second and third wafers W2 and W3. The external pad 155 may be electrically connected to the TSV 120 in the second and third wafers W2 and W3. The bonding pattern 160 may be formed on the external pad 155. Thus, the bonding pattern 160 of the second wafer W2 may face the bonding pattern 160 of the third wafer W3. An insulation layer 115 may be formed between stack structures including the external pad 155 and the bonding pattern 160. The bonding pattern 160 may correspond to the hybrid bonding pad.

When the first to fourth wafers W1˜W4 is bonded to each other, the vertical connection structure VP may be formed through the first to fourth wafers W1˜W4. The horizontal connection structure PP may be formed in a lowermost wafer (i.e., the first wafer W1) and an uppermost wafer (i.e., the fourth wafer W4). The lower horizontal connection structure PPd may be extended in the second direction D2. The upper horizontal connection structure PPu may be extended in the third direction D3.

Therefore, the conductive path that extends in the vertical and horizontal directions may be formed in the first to fourth wafers W1˜W4. When the test bias is applied to one end of the conductive path, the test current may flow through the conductive path. Thus, whether the bonding of the wafers is normal (acceptable) or not may be determined by measuring the test current. Further, because the conductive path may be formed near the semiconductor chip, the position of the bonding error within the wafer may be accurately recognized. In example embodiments, the horizontal connection structure PPu may be extended from a selected one of the multi-layered conductive wirings (or the multi-interconnection layers: 120, 130, 140 or MP).

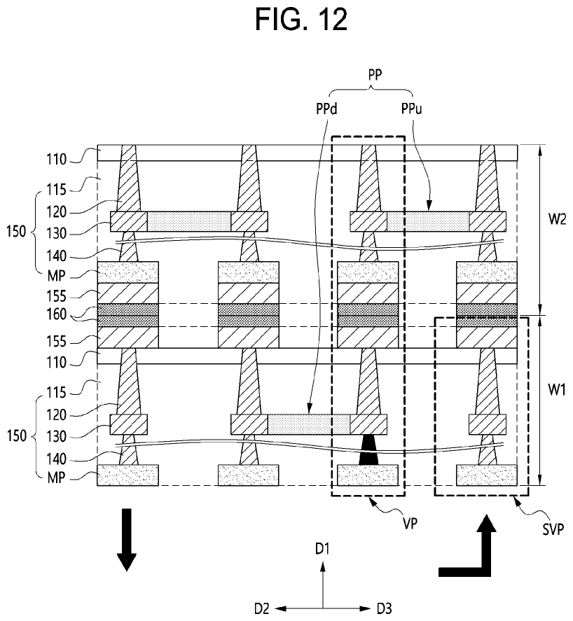

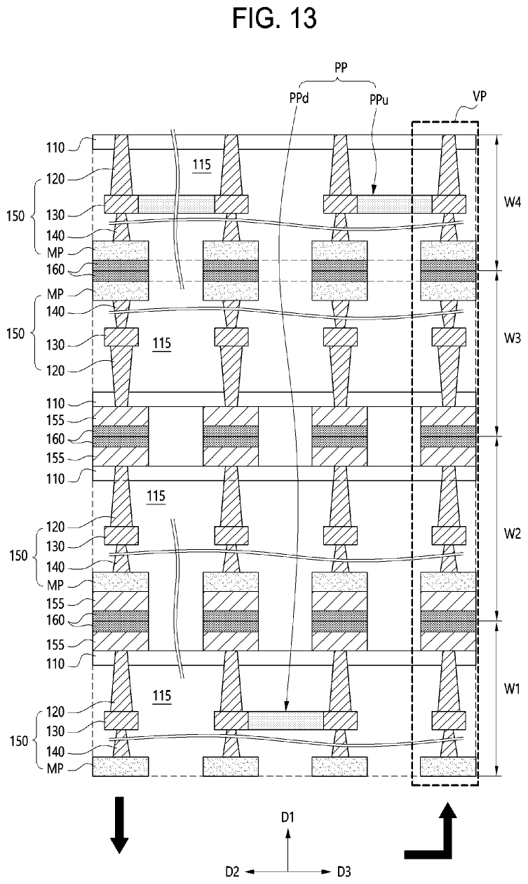

FIG. 12 is an enlarged cross-sectional view illustrating a stack type semiconductor device including two wafers bonded by a face-to-face bonding process in accordance with example embodiments, and FIG. 13 is an enlarged cross-sectional view illustrating a stack type semiconductor device including four wafers bonded by various techniques in accordance with example embodiments.

Referring to FIG. 12, each of the first and second wafers W1 and W2 may include a sub-vertical connection structure SVP and a horizontal connection structure Pd and Pu. The upper surface of the first wafer W1 may face the bottom surface of the second wafer W2. The hybrid bonding pattern 160 may be formed on the upper surface of the first wafer W1 and the bottom surface of the second wafer W2. The first and second wafers W1 and W2 may be bonded to each other through the hybrid bonding process.

An external pad 155 may be formed on the upper surface of the first wafer W1. The external pad 155 may be electrically connected between the bonding pattern 160 and the exposed TSV 120. An external pad 155 may be formed on the bottom surface of the second wafer W2. The external pad 155 may be electrically connected between the monitoring pattern MP and the bonding pattern 160. In example embodiments, the external pad 155 may include an RDL.

Although the first and second wafers W1 and W2 may be stacked in the face-to-face bonding process, when the corresponding sub-vertical connection structures SVP are electrically and physically bonded to each other, the vertical connection structure VP may be formed through the stacked wafers W1 and W2. Further, because the horizontal connection structure PP in the first and second wafers W1 and W2 may be connected between the vertical connection structures VP, the conductive path may be extended in the bonded first and second wafers W1 and W2 along the vertical and horizontal directions.

FIG. 12 may show the two wafers stacked in the face-to-face bonding process. Alternatively, at least three wafers may be hybrid-bonded to each other.

As shown in FIG. 13, each of the first to fourth wafers W1˜W4 may include a sub-vertical connection structures SVP. The first and fourth wafers W1 and W4 may include a horizontal connection structure PPd and PPu respectively configured to connect the adjacent sub-vertical connection structures SVP with each other. As shown in FIG. 12, the first and second wafers W1 and W2 may be bonded to each other through the face-to-face bonding process. The third and fourth wafers W3 and W4 may also be bonded to each other through the face-to-face bonding process. The second and third wafers W2 and W3 may be bonded to each other through the back-to-back bonding process, illustrated with reference to FIG. 9. Although the wafers may be stacked through various techniques, when the facing sub-vertical connection structures SVP are electrically and physically bonded to each other, the vertical connection structure VP may be formed through the first to fourth wafers W1˜W4. Further, because the horizontal connection structure PPd and PPu on the first and fourth wafers W1 and W4, respectively, may be connected between the sub-vertical connection structures SVP, the conductive path may be extended in the bonded first to fourth wafers W1˜W4 along the vertical and horizontal directions.

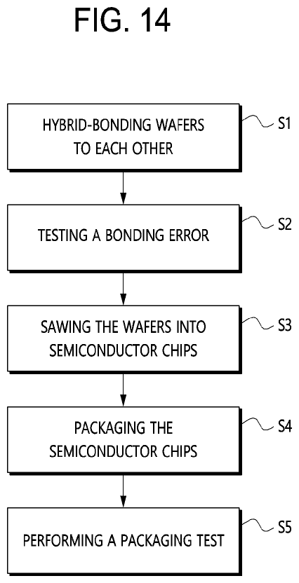

FIG. 14 is a flow chart illustrating a method of manufacturing a stack type semiconductor device in accordance with example embodiments.

Referring to FIG. 14, in step S1, the wafers may be bonded to each other through the hybrid bonding process. Each of the wafers may be divided into the semiconductor chips. The sub-vertical connection structures and the horizontal connection structures may be arranged in the edge region of the semiconductor chip. The sub-vertical connection structure may be formed through each of the wafers. The uppermost and lowermost wafers, among the wafers, may include the horizontal connection structure configured to connect the adjacent sub-vertical connection structures to each other. The horizontal connection structures in the uppermost wafer and the lowermost wafer may be alternately arranged, without facing each other, to form the horizontal and vertical conductive path having a pulse shape (referring to FIG. 7) in the bonded wafers.

After completing the hybrid bonding process, in step S2, the bonding failure of the wafers may be detected by utilizing the conductive path. Particularly, the test bias may be applied to one end of the conductive path. The resulting test current may then be measured at the other end of the conductive path.

When the measured test current is no less than an allowable range, the bonding process may be determined to be normal. In contrast, when the measured test current is lower than the allowable range, the bonding process may be determined to be abnormal. That is, it can be noted that there may be a misalignment between the upper and lower sub-vertical connection structures, or the connection patterns CP may be disconnected from each other due to a crack formed in the bonding process. In example embodiments, the conductive path, before applying the test bias, may be a conductive wiring structure. The conductive path after applying the test bias may be an actual current flow path. The information of the bonding failure that is obtained in step S2 may be stored, for example, in a testing apparatus, a packaging apparatus, a controller configured to control the apparatuses, etc. Following bonding processes may be corrected based on the information of any bonding failure(s).

In step S3, the wafers may then be sawed. However, when bonding failure is determined for all of the bonded wafers, the sawing process might not be performed. If the sawing process is performed, the bonded wafers may be singulated into the stacked chips. In step S4, a packaging process may be performed on the stacked chips to form the stack type package.

The packaging process may include mounting the semiconductor chips on a package substrate and molding the semiconductor chip and the package substrate with a resin. The packaging process might not be performed on any semiconductor chip deemed to have bonding failure. When the abnormal semiconductor chip is packaged together with the normal semiconductor chip, the abnormal semiconductor chip may have been previously treated to make the abnormal semiconductor chip in the stack type package non-operational.

In step S5, the stack type package may then be tested. The test process may include generating the conductive path in the semiconductor chips, which may be bonded in the manner substantially the same as that illustrated in step S2, to transmit the test current in the vertical and horizontal directions. A test voltage may be applied to the package through an external terminal. When an error is detected in the package test, not the wafer test, it can be noted that the packaging process may be abnormal, and the hybrid bonding process may be normal. Thus, the packaging process may be corrected based on the detected information.

The vertical and horizontal current path may flow through the stacked semiconductor chip in the package. A problem, such as a crack of the semiconductor chip, may be tested based on the amount of the test current that is transmitted to the vertical and horizontal current path.

Although not depicted in drawings, external terminals, such as solder balls, may then be mounted on the bottom surface of the stack type package.

Additionally, while various embodiments in this disclosure described a horizontal connection structure connecting adjacent vertical connection structures for ease of description, an embodiment of the disclosure need not be so limited. That is, an embodiment may have a horizontal connection structure connect non-adjacent vertical connection structures.

According to example embodiments, the conductive path including the vertical connection structure and the horizontal connection structure may be formed in each of the regions of the semiconductor chip in which the test pads are arranged. After bonding the wafers to each other, the test bias may be applied to one end of the conductive path to provide the test current through the conductive path. The bonding error of the bonded wafers may be detected by determining the value of the test current.

In example embodiments, the semiconductor chips may be hybrid-bonded to each other using the bonding patterns. Alternatively, any semiconductor chips may be stacked during the hybrid bonding process and other semiconductor chips may be stacked in a bump bonding process. Further, the test process of example embodiments may be applied to various memory devices, such as a 3DS memory device and a high bandwidth memory (HBM).

The above described embodiments of the present disclosure are intended to illustrate and not to limit any embodiment. Various alternatives and equivalents are possible. The disclosure is not limited by the embodiments described herein. Nor is the disclosure limited to any specific type of semiconductor device. Another additions, subtractions, or modifications are obvious in view of the present disclosure and are intended to fall within the scope of the appended claims.

What is claimed is:

1. A stack type semiconductor device comprising:
a stack wafer structure including a plurality of wafers that are hybrid-bonded to each other, each of the wafers including one or more semiconductor chips; and
a conductive path including a plurality of vertical connection structures formed through the stack wafer structure and one or more of horizontal connection structures configured to connect the vertical connection structures.

2. The stack type semiconductor device of claim 1, wherein the horizontal connection structures comprise an upper horizontal connection structure, connected to an upper end of a vertical connection structure, among the plurality of vertical connection structures, and a lower horizontal connection structure, connected to a lower end of the vertical connection structure,
wherein the upper horizontal connection structure connects the vertical connection structure to a first adjacent vertical connection structure, and
wherein the lower horizontal connection structure connects the vertical connection structure to a second adjacent vertical connection structure, the second adjacent vertical connection structure being different from the first adjacent vertical connection structure.

3. The stack type semiconductor device of claim 2, wherein the upper and lower horizontal connection structures are positioned in different wafers.

4. The stack type semiconductor device of claim 2, wherein the upper horizontal connection structure does not overlap with the lower horizontal connection structure.

5. The stack type semiconductor device of claim 1, wherein the vertical connection structure comprises sub-vertical connection structures that are formed through each of the wafers, and
wherein each of the sub-vertical connection structures comprises:
a through silicon via (TSV) formed in the semiconductor chip;
a monitoring pattern arranged in the TSV;
a multi-layered conductive wiring arranged in the semiconductor chip to electrically connect the TSV to the monitoring pattern; and
a hybrid bonding pattern formed on the monitoring pattern.

6. The stack type semiconductor device of claim 5, wherein the bonding pattern comprises a copper layer.

7. The stack type semiconductor device of claim 5, wherein the bonding pattern comprises at least one metal pattern and at least one insulation pattern that is alternately arranged.

8. The stack type semiconductor device of claim 5, wherein the horizontal connection structure is extended from a layer in the multi-layered conductive wiring.

9. The stack type semiconductor device of claim 1, wherein the conductive path is in one or both of a main region of the semiconductor chip and an edge region of the semiconductor chip.

10. The stack type semiconductor device of claim 9, wherein at least one test pad is in the edge region or the main region of the semiconductor chip.

11. The stack type semiconductor device of claim 1, wherein at least one of the horizontal connection structures is configured to connect adjacent vertical connection structures.

12. A stack type semiconductor device comprising:
first and second wafers bonded to each other via a plurality of bonding patterns, the plurality of bonding patterns including layers and each of the first and second wafers including one or more semiconductor chips;
a conductive path configured to extend through the first and second wafers;
a transmitter connected to a first end of the conductive path to receive a test voltage; and
a receiver connected to a second end of the conductive path to detect a current that is generated from the test voltage.

13. The stack type semiconductor device of claim 12, wherein the conductive path comprises:
a plurality of vertical connection structures formed through the first and second wafers; and
a plurality of horizontal connection structures configured to connect the vertical connection structures with each other.

14. The stack type semiconductor device of claim 13, wherein each of the horizontal connection structures comprises:
a first horizontal connection structure positioned in the first wafer to connect a first vertical connection structure, among the plurality of vertical connection structures, to a second vertical connection structure, among the plurality of vertical connection structures, the second vertical connection structure being adjacent to the first vertical connection structure; and
a second horizontal connection structure positioned in the second wafer to connect the second vertical connection structure to a third vertical connection structure, among the plurality of vertical connection structures, the third vertical connection structure being adjacent to the second vertical connection structure,
wherein the first and second horizontal connection structures are not overlapped with each other.

15. The stack type semiconductor device of claim 12, wherein the conductive path is arranged in a region of the semiconductor chip of the first and second wafers.

16. The stack type semiconductor device of claim 12, wherein a bonding pattern, among the plurality of bonding patterns, comprises at least one insulation pattern and at least one copper pattern that are alternately arranged.

17. A method of manufacturing a stack type semiconductor device, the method comprising:
is forming bonded wafers by hybrid-bonding a plurality of wafers;
providing a test current to the bonded wafers by applying a test bias to a conductive path through the bonded wafers, wherein an open circuit in the conductive path results in a test current of zero amperes;
determining a bonding error of the bonded wafers by measuring the test current;
sawing the bonded wafers into a plurality of semiconductor chips; and
packaging each of the semiconductor chips.

18. The method of claim 17, further comprising forming a conductive path in the hybrid-bonded wafers to transmit the test current,
wherein the conductive path comprises:
a plurality of vertical connection structures formed through the hybrid-bonded wafers; and
a plurality of horizontal connection structures configured to connect the vertical connection structures with each other.

19. The method of claim 18, further comprising additionally applying the test current to the packaged semiconductor chip to detect a packaging error.
